(19) United States
(12) Patent Application Publication
(10) Pub. No.: US 2003/0017658 A1
(43) Pub. Date: Jan. 23, 2003

(54) Non-single crystal film, substrate with non-single crystal film, method and apparatus for producing the same, method and apparatus for inspecting the same, thin film trasistor, thin film transistor array and image display using it

(76) Inventors: Hikaru Nishitani, Nara-shi (JP); Makoto Yamamoto, Takarazuka-shi Hyogo (JP); Yoshinao Taketomi, San Diego, CA (US); Shinchi Yamamoto, Hirakata-shi Osaka (JP); Masanori Miura, Ibaraki-shi Osaka (JP)

Correspondence Address: Parkhurst & Wendel, Suite 210, 1421 Prince Street, Alexandria, VA, 22314-2805, US

(21) Appl. No.: 10/203,517

(22) PCT Filed: Feb. 15, 2001
(86) PCT No.: PCT/JP01/01085

(30) Foreign Application Priority Data
Feb. 15, 2000 (JP) 2000-36123
Feb. 15, 2000 (JP) 2000-36128

(51) Int. Cl. H01L 21/00; H01L 21/26; H01L 21/84

(52) U.S. Cl. 438/149; 438/166; 438/795

(57) ABSTRACT

The present invention provides methods of fabricating a non-single crystal film, whereby variations in crystal grain size are reduced and the periodicity of grain size is improved. The methods of fabricating a non-single crystal film of the present invention include: first, forming a non-single crystal film and then optimizing laser irradiation by monitoring diffracted light; and second, performing laser irradiation with a substrate having been cooled.

### TECHNICAL FIELD

The present invention relates to a non-single crystal film and a substrate with a non-single crystal film, a method of and apparatus for fabricating such film and substrate, a method of and apparatus for testing such film and substrate, and a thin film transistor, a thin film transistor array, and an image display device.

### BACKGROUND ART

In recent years, active research and development has been conducted for image display devices utilizing thin film transistors (TFTs) as the pixel switching element, such as liquid crystal display devices and organic EL display devices. Under such circumstances, noting the fact that a TFT using polysilicon for the channel region has carrier mobility significantly higher than that of a TFT using amorphous silicon for the channel region, a display device having polysilicon TFTs and driving circuit formed on the same substrate (driving circuit-contained display device) has been suggested and is under research and development.

A TFT has, on a substrate such as a silica glass or glass substrate, a semiconductor film divided into sections such as a channel region, a drain region, and a source region, a gate electrode insulated from the semiconductor film, and a drain electrode and a source electrode electrically connected to the drain and source regions, respectively.

For methods of fabricating a semiconductor film of a TFT, a laser annealing method is often utilized in which an amorphous film such as an amorphous silicon film is irradiated with a laser beam and then fused and crystallized to form a non-single crystal film such as a polysilicon film. In the laser annealing method, generally, as the laser beam, an argon laser, an excimer laser using, for example, KrF gas, XeCl gas, or the like is utilized. For example, in the case of using the excimer laser, a beam of several centimeter square emitted from a light source is formed into a rectangular or line-shaped beam with uniform light intensity, via an optical system called homogenizer, and then the beam is irradiated to an amorphous film to crystallize. In the image display device, in particular, uniformity of the screen is very important, and thus a method where a large area is uniformly crystallized using a relatively large beam is suitably employed. Hence, a method where a line-shaped beam is irradiated as scanning is generally employed.

In crystallizing using such a laser annealing method, improvement in uniformity of crystallinity is the greatest object. When there are variations in crystallinity in the pixel region, non-uniformity is caused on the display screen, and when there are variations in crystallinity in the driving circuit region, variations in circuit properties are caused, in which case there is a possibility that the circuit does not operate. Defects resulting from these variations are only found after the fabrication process has been completed, bringing about a great loss.

In order to solve the above-described problems, the following methods are suggested: (1) a reflective film or absorbing film is covered on a part of the irradiation surface to control the light absorption of the thin film surface, thereby forming an intensity distribution and the direction of crystal growth is induced; (2) with the substrate having been heated (400° C.), laser irradiation is performed, whereby crystallization is smoothly progressed (Extended Abstracts of the 1991 International Conference on Solid State Devices and Materials, Yokohama, 1991, p.p. 623-625, and the like); (3) as shown in FIG. 17, a test beam 302 is irradiated to a non-single crystal film 301 having been treated with an excimer laser beam 300, and a transmitted light 303 and a reflected light 304 of the test beam are detected by a transmitted light detector 305 and a reflected light detector 306, respectively, to detect the degree of crystallization progress (Japanese Unexamined Patent Publication No. 10-144621 and the like); and (4) Raman spectrometry, an observation using an atomic force microscope, a cross-sectional SEM observation, an X-ray diffraction technique, and the like.

However, the above-described methods have the following problems, and thus do not sufficiently meet the latest technological trends which aim to realize multidimensional accumulation and further cost reduction.

The method (1) described above requires an additional step of forming a reflective film and the like, and thus the fabrication process becomes complicated, causing a cost increase.

Similarly, the method (2) described above requires a heating step, and thus a reduction in productivity is brought about. In addition, the method has a problem of low yield.

With the method (3) described above, although a great change from a-Si to p-Si can be detected, detection sensitivity is not sufficient because a change in the reflected or transmitted light is small during the process where the state of p-Si having been crystallized is changing slightly.

For the method (4) described above, it is difficult to apply, while the crystallization process is progressing, any of the methods. Moreover, since each method evaluates only at very regional measuring points, it is difficult to see the crystallinity of the entire substrate in a short period of time.

### DISCLOSURE OF THE INVENTION

In view of the foregoing and other problems, it is an object of the present invention to provide a method of fabricating a non-single crystal film by optimizing laser irradiation conditions while monitoring the crystallinity in the irradiated region in real time and with high sensitivity, an apparatus for fabricating such a film, and a non-single crystal film obtained using such an apparatus.

It is another object of the present invention to provide a method of testing a non-single crystal film with high sensitivity and an apparatus for carrying out such a test.

It is still another object of the present invention to provide a method of fabricating a non-single crystal film having no variations in properties such as mobility and Vt properties, which is easily obtained by cooling the substrate without the need to control a laser beam within a narrow irradiation energy range, an apparatus for fabricating such a film, and a non-single crystal film and a substrate with a non-single crystal film obtained using such an apparatus.

It is yet another object of the present invention to provide a thin film transistor using the above-described non-single crystal film as the semiconductor film, a thin film transistor array having such a thin film transistor formed on the substrate, and an image display device using such a thin film transistor array.

A method of fabricating a non-single crystal film according to a first aspect of the present invention may be such that in a method of fabricating a non-single crystal film fabricated by irradiating a laser beam to an amorphous film or microcrystalline film, crystallization or recrystallization is carried out by irradiating a test beam to a region where the laser beam has been irradiated and optimizing an irradiation condition of the laser beam so that a measured value of diffracted light generated from the non-single crystal film becomes a predetermined value.

A method of fabricating a non-single crystal film according to a second aspect of the present invention may be such that in the method described in the first aspect, the measured value of the diffracted light is a light intensity of the diffracted light.

A method of fabricating a non-single crystal film according to a third aspect of the present invention may be such that in the method described in the first aspect, the irradiation condition of the laser beam is at least one selected from the group consisting of energy, the number of irradiation times, frequency, irradiation interval, scanning speed, and beam intensity distribution.

A method of fabricating a non-single crystal film according to a fourth aspect of the present invention may be such that in a method of fabricating a non-single crystal film fabricated by irradiating a laser beam to an amorphous film or microcrystalline film as scanning, crystallization or recrystalization is carried out by irradiating a test beam to a region where the laser beam has been irradiated, recording measured values of diffracted light generated from the non-single crystal film, and irradiating a laser beam again to a region whose measured value does not match a predetermined value.

An apparatus for fabricating a non-single crystal film according to a fifth aspect of the present invention may comprise: a laser beam; an optical system for forming a laser beam into a predetermined shape; a light source for a test beam; and a diffracted light detector, wherein crystallization or recrystallization is carried out by irradiating a test beam from the light source to a non-single crystal film fabricated using the laser beam formed by the optical system, detecting, by the diffracted light detector, diffracted light generated from the non-single crystal film, and optimizing an irradiation condition of the laser beam so that a measured value obtained by the detection becomes a predetermined value.

An apparatus for fabricating a non-single crystal film according to a sixth aspect of the present invention may be such that in the apparatus described in the fifth aspect, the measured value of the diffracted light is a light intensity of the diffracted light.

An apparatus for fabricating a non-single crystal film according to a seventh aspect of the present invention may be such that in the apparatus described in the fifth aspect, the irradiation condition of the laser beam is at least one selected from the group consisting of energy, the number of irradiation times, frequency, irradiation interval, scanning speed, and beam intensity distribution.

A method of testing a non-single crystal film according to an eighth aspect of the present invention may be such that a non-single crystal film is irradiated with a test beam and diffracted light generated from the non-single crystal film is detected.

A method of testing a non-single crystal film according to a ninth aspect of the present invention may be such that in the method described in the eighth aspect, the diffracted light is divided into wavelengths.

A method of testing a non-single crystal film according to a tenth aspect of the present invention may be such that in the method described in the eighth aspect, an angle distribution or position distribution of the diffracted light is measured.

An apparatus for testing a non-single crystal film according to an eleventh aspect of the present invention may comprise: a light source for a test beam; and a diffracted light detector, wherein a non-single crystal film is irradiated with a test beam from the light source and an intensity of diffracted light generated from the non-single crystal film is detected.

An apparatus for testing a non-single crystal film according to a twelfth aspect of the present invention may be such that means for dividing the diffracted light into wavelengths is provided.

An apparatus for testing a non-single crystal film according to a thirteenth aspect of the present invention may be such that the diffracted light detector is a device for measuring an angle distribution or position distribution of the light intensity of the diffracted light.

A method of fabricating a non-single crystal film according to a fourteenth aspect of the present invention may comprise at least: depositing an amorphous film or microcrystalline film on a substrate; and crystallizing, by fusion, the amorphous film or the microcrystalline film by irradiating a laser to the amorphous film or the microcrystalline film, thereby forming a non-single crystal film, wherein the crystallizating is carried out with the substrate having been cooled.

An apparatus for fabricating a non-single crystal film according to a fifteenth aspect of the present invention may be such that in the method described in the fourteenth aspect, in the crystallizing, a temperature of the substrate is maintained at 10° C. or lower.

A method of fabricating a non-single crystal film according to a sixteenth aspect of the present invention may be such that in an apparatus for fablicating a non-single crystal film fabricated by irradiating a laser beam to an amorphous film or microcrystalline film formed on a substrate, means for cooling the substrate is provided.

An apparatus for fabricating a non-single crystal film according to a seventeenth aspect of the present invention may be such that in the device described in the sixteenth aspect, means for measuring a temperature of the substrate, means for heating the substrate, and means for controlling the means for cooling the substrate and the means for heating the substrate, based on a measured value obtained by the means for measuring the temperature of the substrate, are provided.

A non-single crystal film according to an eighteenth aspect of the present invention may be such that in a non-single crystal film formed on a substrate, the film satisfies the following expression (1):

Δλ/λ≦0.3 (1)

where λ (nm) is a wavelength of a main peak of diffracted light obtained by light irradiation and Δλ (nm) is a half-width of the wavelength of the main peak.

A non-single crystal film according to a nineteenth aspect of the present invention may be such that in a non-single crystal film formed on a substrate, the film satisfies the following expression (2):

sin(Φ+ΔΦ/2)/sin Φ≦0.15 (2)

where Φ (degree) is an exit angle of strongest diffracted light obtained by monochromatic light irradiation and ΔΦ is a half-width of the angle of the diffracted light.

A non-single crystal film according to a twentieth aspect of the present invention may be such that the film described in the eighteenth aspect satisfies the following expression (3):

σ/λ≦0.15 (3)

where σ represents a standard deviation.

A non-single crystal film according to a twenty-first aspect of the present invention may be such that the film described in the nineteenth aspect satisfies the following expression (4):

σ/(sin Φ)≦0.15 (4)

where σ represents a standard deviation.

A non-single crystal film according to a twenty-second aspect of the present invention may be such that in a non-single crystal film formed on a substrate, a surface of the thin film has regions having differing peak wavelengths of diffracted light generated by light irradiation.

A non-single crystal semiconductor film according to a twenty-third aspect of the present invention may be such that in a non-single crystal semiconductor film for a driving circuit-contained liquid crystal display device, a region corresponding to a pixel portion and a region corresponding to a driving circuit portion have differing peak wavelengths of diffracted light.

A non-single crystal film according to a twenty-fourth aspect of the present invention may be such that in the film described in the twenty-second aspect, the peak wavelengths between the regions differ by 200 nm or more.

A non-single crystal film according to a twenty-fifth aspect of the present invention may be such that in a -single crystal film formed on a substrate, a surface of the thin film has regions having differing exit angles of diffracted light.

A non-single crystal semiconductor film according to a twenty-sixth aspect of the present invention may be such that in a non-single crystal semiconductor film for a driving circuit-contained liquid crystal display device, a region corresponding to a pixel portion and a region corresponding to a driving circuit portion have differing exit angles of diffracted light.

A non-single crystal film according to a twenty-seventh aspect of the present invention may be such that in a non-single crystal film formed on a substrate, a peak shift quantity by Raman spectrometry is 3 cm⁻¹ or less than that of single crystal.

A substrate with a non-single crystal film according to a twenty-eighth of the present invention may be such that in a substrate with a non-single crystal film fabricated by irradiating a laser beam to an amorphous film or microcrystalline film formed on a substrate surface with a base film interposed therebetween, an impurity concentration of the base film is 0.001% or less than that of the substrate.

A non-single crystal film according to a twenty-ninth aspect of the present invention may be such that in a non-single crystal film formed on a substrate, a surface of the thin film has a region in which diffracted light is generated by light irradiation and the diffracted light can be detected.

A non-single crystal film according to a thirtieth aspect of the present invention may be such that in the non-single crystal film described in the twenty-ninth aspect, the region includes a rectangle such that at least one side thereof is 0.5 mm or more.

A thin film transistor according to a thirty-first aspect of the present invention may be such that a non-single crystal film described in any one of the eighteenth to thirtieth aspects is used as a semiconductor film.

A thin film transistor array according to the thirty-second aspect of the present invention may be such that the thin film transistor described in the thirty-first aspect is formed on a substrate.

An image display device according to a thirty-third aspect of the present invention may be such that the thin film transistor array described in the thirty-second aspect is used.

### BRIEF DESCRIPTION OF THE DRAWINGS

FIG. 1 is a structural view schematically showing the main part of an apparatus for fabricating a polysilicon film according to Embodiment 1 of the present invention.

FIG. 2 is a graph showing changes in the intensity of diffracted light.

FIG. 3 is a structural view schematically showing the main part of an apparatus for testing a polysilicon film according to Embodiment 2 of the present invention.

FIG. 4 is a cross-sectional view schematically showing an example of a thin film transistor according to Embodiment 3 of the present invention.

FIG. 5 is a structural view schematically showing an apparatus for fabricating a polysilicon film according to Embodiment 4 of the present invention.

FIGS. 6(a) to 6(d) are graphs showing the relationship between ELA energy and TFT mobility.

FIG. 7 is a structural view schematically showing an apparatus for fabricating a polysilicon film according to Embodiment 5 of the present invention.

FIG. 8 is a structural view schematically showing an apparatus for fabricating a polysilicon film according to Embodiment 6 of the present invention.

FIG. 9 is a graph showing the relationship between the wavelength distribution of diffracted light and the intensity of diffracted light.

FIG. 10 is a graph showing the relationship between substrate temperature and yield.

FIGS. 11(a) and 11(b) are graphs showing the TFT mobility and the peak wavelength of diffracted light at measuring points of a polysilicon film. FIG. 11(a) shows the case of a prior art polysilicon film and FIG. 11(b) shows the case of a polysilicon film of the present invention.

FIG. 12 is a graph showing the relationship between the exit angle distribution of diffracted light and the amount of diffracted light.

FIG. 13 is a graph showing the relationship between ELA energy and Raman peak position.

FIG. 14 is a graph showing the relationship between peak shift quantity and TFT mobility.

FIG. 15 is a plan view showing the case where there are regions having differing peak wavelengths of diffracted light generated when light is irradiated or having differing exit angles of the strongest diffracted light.

FIG. 16 is a graph showing the distance from the interface between a glass substrate and a base film and impurity concentration.

FIG. 17 is a structural view schematically showing an example of a prior art testing apparatus.

Description of the Reference Numerals

| | |
|---|---|
| 1. | Glass substrate |
| 2. | Amorphous silicon film |
| 3. | Test beam |
| 4. | Diffracted light detector |
| 5. | Laser beam |
| 6. | Polysilicon film |
| 7. | Micro-rough structure |
| 8. | Diffracted light |
| 9. | Substrate-transport stage |
| 10. | Cylindrical lens |

### BEST MODE FOR CARRYING OUT THE INVENTION

The embodiments of the present invention are explained below with reference to the drawings. It is supposed that for a non-single crystal film Group IV semiconductors such as Si and Ge are mainly used. Although it has been confirmed that the use of Group III-V semiconductors such as GaAs or Group II-VI semiconductors such as ZnSe is effective as well, the following embodiments are described for the case, as an example, of silicon (Si) which is most common.

### EMBODIMENT 1

Embodiment 1 is such that diffracted light generated by a micro-rough configuration of the surface of a p-Si film is utilized.

First, the process how a group of inventions represented by Embodiment 1 was completed is explained below.

The present inventors found, in the process of intensive study directed toward preventing property variations from arising in a non-single crystal semiconductor film, that a polysilicon film (p-Si film) fabricated by irradiation of excimer laser, which is ultraviolet light, has a substantially regular rough structure present on the surface thereof and this rough structure has a strong correlation with the degree of crystallization and that the polysilicon film shows various aspects depending on laser irradiation conditions. In addition, the correlation between crystallinity and TFT properties has been confirmed.

The present inventors therefore irradiated a test beam to a crystalline silicon film fabricated under certain crystallization conditions, and spectral light from green to violet was observed. The present inventors thus found that how the spectral light appears varies greatly with the irradiation angle of test beam and with the observation angle. Moreover, the present inventors found that by this observation it is possible to see the state of the entire substrate in a short period of time and further to identify, at a glance, portions having differing degrees of crystallization (in most cases, portions with low crystallinity).

Consequently, the present inventors confirmed that light is diffracted by the rough structure of the p-Si film surface, thereby generating spectral light. In addition, it was confirmed that when the parameters for crystallization conditions, such as the intensity of laser beam, the number of irradiation times, oscillation frequency, and laser scanning speed, are changed, the angle, wavelength, and intensity at which diffracted light is observed also slightly change.

From the above, the present inventors found that by irradiating a test beam to a region where the laser beam has been irradiated and monitoring diffracted light from the non-single crystal film, it is possible to detect the degree of crystallization progress in real time, using the measured values (such as light intensity) of the diffracted light as the index and that it is possible to realize uniform crystallinity by giving feedback, based on the results of the detection, to the laser irradiation conditions and controlling irradiation conditions and as a result, it is possible to suppress variations in film properties. Thus, the group of inventions represented by Embodiment 1 was completed.

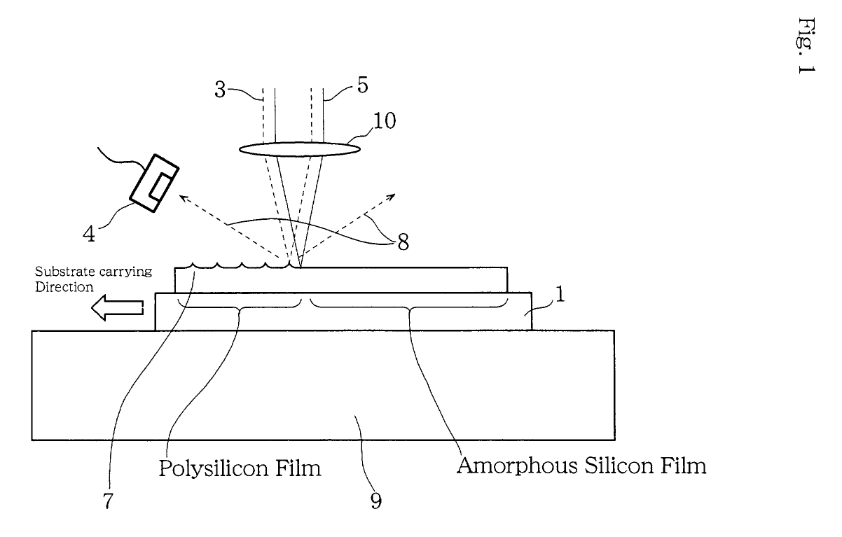

FIG. 1 is a structural view schematically showing the main part of an apparatus for fabricating a polysilicon film according to the present embodiment. Reference numeral 1 indicates a glass substrate, reference numeral 2 an amorphous silicon film (a-Si film), reference numeral 3 a test beam generated by a test beam oscillator (not shown in the figure), reference numeral 4 a diffracted light detector, reference numeral 5 an excimer laser beam generated by an excimer laser oscillator (not shown in the figure), reference numeral 6 a polysilicon film (p-Si film), reference numeral 7 a micro-rough structure, reference numeral 8 diffracted light, and reference numeral 9 a substrate-transport stage. Note that an optical system for forming an excimer laser beam into a line beam of 350 μm in width is not shown in the figure except for a cylindrical lens 10 that composes a part thereof.

A method of fabricating a polysilicon film using a fabrication apparatus with the above-described configuration is as follows.

First, a glass substrate 1 having an a-Si film 2 formed thereon is prepared and the glass substrate 1 is placed on a substrate-transport stage 9. The glass substrate with an a-Si film can be obtained, for example, by depositing an SiO₂ base film of about 300 nm in thickness (not shown in the figure) on a glass substrate by the TEOS CVD method or the like so as to remove impurities from the glass, and then depositing an a-Si film 2 of about 50 nm in thickness by the plasma CVD method. In order to remove hydrogen in the a-Si film fabricated by the plasma CVD method, usually as a dehydrogenation step, a heat treatment is performed at 450° C. for one hour.

Next, as allowing the substrate-transport stage 9 to move horizontally and in both the lengthwise and crosswise directions, an excimer laser beam 5 with values greater than the threshold value for crystallization is irradiated to the a-Si film 2. Thereby, the a-Si is fused and crystallized, becoming p-Si.

Subsequently, a test beam 3 is irradiated to a region where the excimer laser beam has been irradiated, and diffracted light 8 of the test beam is monitored by a diffracted light detector 4. At this point, the test beam 3 that reached a region not having been crystallized only makes mirror reflection due to the smoothness of the surface of the a-Si 2 and does not reach at all the diffracted light detector 4 disposed outside the axis. In addition, in a p-Si film 6 formed by irradiation in such a laser energy range that is relatively lower than the thresholds for crystallization, the rough structure of the surface thereof is coarse and has low regularity, and therefore diffracted light is hardly generated and only a slight amount of scattered light is generated. On the other hand, the surface of the p-Si film 6 treated in such a laser energy range that increases crystallinity has a substantially regular micro-rough structure 7, which reflects the crystallinity. Therefore, when the test beam 3 is irradiated to this region, diffracted light 7 with sharp directivity is generated and the light reaches the detector 4. This light greatly differs from the scattered light level, and thus these two different lights can be clearly distinguished. Accordingly, it is possible to see the process where the state of the p-Si having been crystallized is changing slightly, and therefore the most suitable crystallization conditions can be determined with high sensitivity.

Next, based on the measured values of the light intensity of diffracted light and the like, if there is a region where crystallization has not sufficiently been performed, a laser beam is irradiated again to such a region. Optimization is carried out in such a way. Thus, a p-Si film is obtained.

In general, the amount of laser energy necessary for crystallization depends greatly on the thickness of an a-Si film. Accordingly, in the case where there are variations in the thicknesses of a-Si films between a plurality of substrates or in the substrate plane, the optimum laser energy turns out to be different from portion to portion. Conventionally, all substrates were treated with fixed laser energy and therefore the variations in thickness directly resulted in variations in properties. However, according to the present embodiment, it is possible to carry out the crystallization process without a great loss by, for example, the steps as will be described below, while determining optimal conditions for each substrate.

First, a laser beam is irradiated to the periphery of a substrate and the laser energy is controlled to the level at which diffracted light can be detected. The laser energy here is referred to as E0. Normally, an a-Si film is fabricated such that the film thickness is thicker by about 10% at the center of the substrate than the periphery of the substrate, and therefore the appropriate energy for the center of the substrate is somewhat higher than E0. Thereafter, by driving the substrate-transport stage and performing laser beam irradiation over the entire substrate surface, a uniform non-single crystal film can be fabricated over the entire substrate because laser energy is adjusted to the center of the margin in advance.

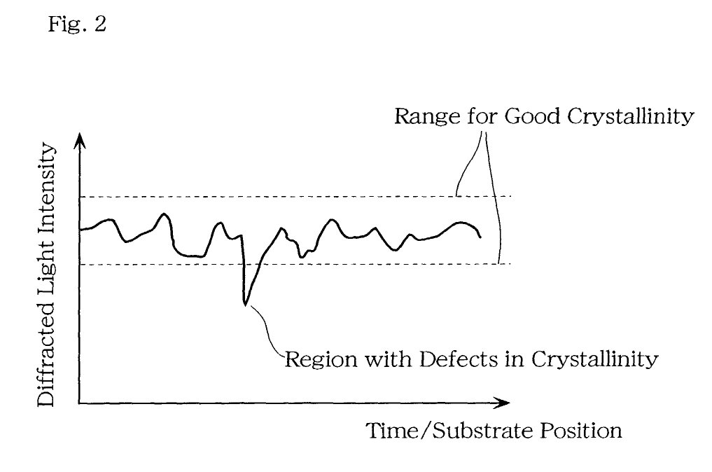

Note, however, that even when the above-described technique is employed, there is a possibility of causing, before completion of the laser irradiation over the entire substrate surface, an irregular shot due to pulse instability of an excimer laser. Even in such a case, since the diffracted light is monitored, it is possible to keep a record of the time when the diffracted light level deviated from a specified range, that is, where on the substrate an irregular shot occurred (see FIG. 2). By performing laser irradiation again based on this information, variations in crystallinity caused by the irregular shot can be corrected, which in turns prevents a loss due to generation of defectives.

Note that the test beam can be white light or a monochromatic light laser beam such as an He—Ne laser beam, an Ar laser beam, and a YAG laser beam, and that it is preferable that the test beam be formed so as to substantially correspond to a region where an excimer laser beam has been irradiated. In addition, it is preferable that a filter for cutting the wavelength of an excimer laser beam be disposed in front of the diffracted light detector so as to detect only the diffracted light of the test beam.

### EMBODIMENT 2

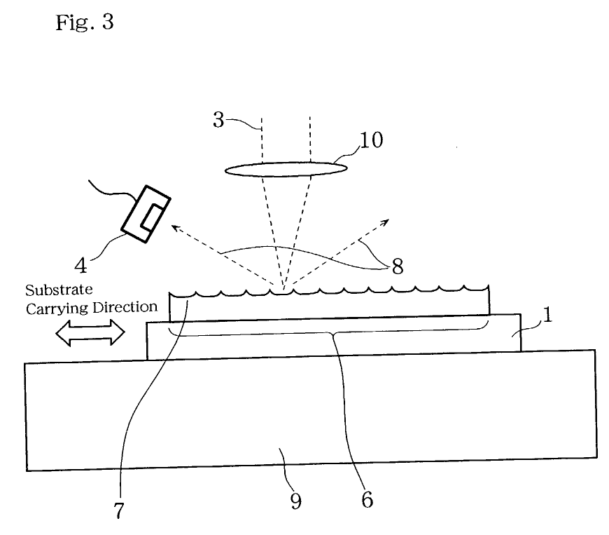

FIG. 3 is a structural view schematically showing the main part of an apparatus for testing a polysilicon film. This testing apparatus has a configuration such that the oscillator of excimer laser beam 5 is removed from the fabrication apparatus described in Embodiment 1.

A method of testing a polysilicon film using an apparatus with the above-described configuration is carried out as follows.

First, in the same manner as that described above, an a-Si film is formed on a glass substrate, and then using a conventionally known laser annealing system, the a-Si film is fused and crystallized to form a p-Si film, thereby preparing a glass substrate 1 with a p-Si film 6.

Next, the glass substrate 1 with the p-Si film 6 is placed on a substrate-transport stage 9. As allowing the substrate-transport stage 9 to move, a test beam 3 is irradiated to the p-Si film 6. At this point, diffracted light generated by a micro-rough structure 7 of the p-Si film 6 is detected by a diffracted light detector 4 and recorded. In such a manner, it is possible to test the crystallization state of the p-Si film 6.

With such a testing apparatus, regions having crystallization defects can be clearly found, and therefore by performing laser annealing again using a conventional laser annealing system, a p-Si film without variations in crystallinity can be fabricated.

### EMBODIMENT 3

This embodiment relates to a thin film transistor that utilizes, as the semiconductor film, a non-single crystal film described in each of the foregoing embodiments.

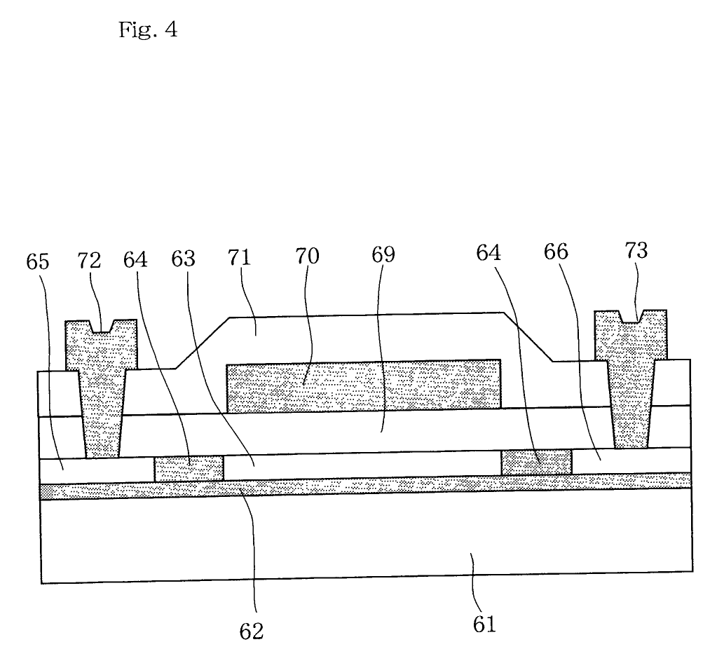

FIG. 4 shows one example of a thin film transistor. Reference numeral 61 indicates a glass substrate and reference numeral 62 a base film. Reference numerals 63, 64, 65, and 66 indicate a channel region, an LDD region, a source region, and a drain region, respectively, and these compose a semiconductor film 67. Reference numeral 69 indicates a gate insulating film, reference numeral 70 a gate electrode, reference numeral 71 an interlayer insulating film, reference numeral 72 a source electrode, and reference numeral 73 a drain electrode.

A thin film transistor with the above-described configuration can be fabricated, for example, as follows.

First, in the same manner as that described above, a p-Si film is formed on a glass substrate, and then the film is patterned by photolithography and dry etching. Subsequently, a gate insulating film made of SiO₂ with a thickness of 100 nm is formed by, for example, the TEOS CVD method. Next, an aluminum film is sputtered and patterned into a given shape by etching, thereby forming a gate electrode. Then, using the gate electrode as a mask, the source and drain regions are implanted with the necessary kinds of dopants, using an ion doping system. Further, an interlayer insulating film made of Si oxide is deposited by the atmospheric pressure CVD method to cover the gate insulating film, and a contact hole that reaches each of the source and drain regions of the p-Si film is made in the interlayer insulating film and the Si oxide film. Next, a titanium film and an aluminum film are sputtered and patterned into a given shape by etching, thereby forming a source electrode and a drain electrode. Thus, a thin film transistor as shown in FIG. 4 is obtained.

The thin film transistor thus obtained can be used in thin film transistor arrays and image display devices such as liquid crystal display devices, organic EL display devices, and the like.

### EMBODIMENT 4

The present embodiment is such that the substrate is cooled prior to laser annealing.

First, the process how a group of inventions represented by the present embodiment was completed is described below.

The present inventors studied, in the process of intensive study directed towards realizing higher properties of p-Si film, the relationship between substrate temperature and excimer laser annealing (ELA) energy, and consequently found that the lower the substrate temperature, the larger the energy range in which a p-Si film without defects can be formed. When polycrystalline silicon has many grain boundaries, many carriers diffuse, which in turn reduces mobility. Therefore, it is preferable to irradiate a laser beam so that the grain size is as large as about 1 μm. However, there is a problem that high-energy irradiation causes deterioration and ablation. Thus, the laser energy range has a certain range in which sufficient mobility is realized without damaging the state of the film. It was found that such a range has a dependency on the substrate temperature.

From this knowledge, the present inventors found that when the substrate is cooled so that the substrate temperature is lower than room temperature, the allowable range of laser energy is increased and therefore a p-Si film without deterioration and ablation can be formed. Thus, the group of inventions represented by the present embodiment was completed.

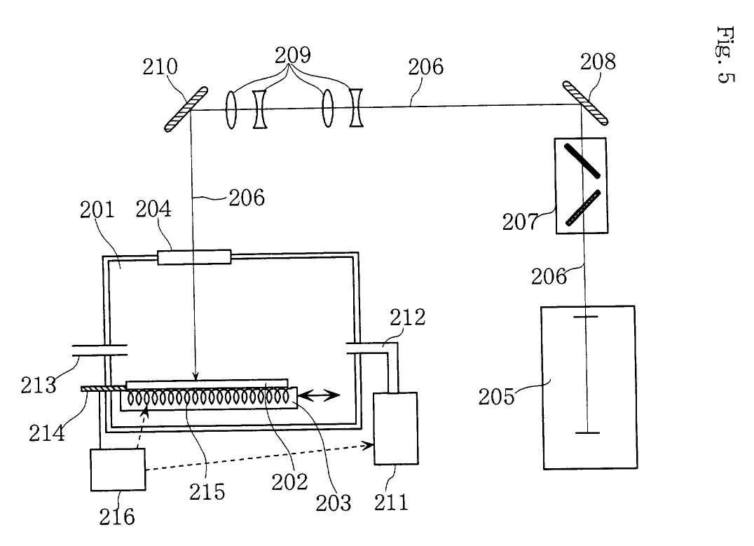

FIG. 5 is a structural view schematically showing an apparatus for fabricating a polysilicon film (laser annealing apparatus) according to the present embodiment.

This fabrication apparatus is such that in a process chamber 201 there is arranged a substrate-transport stage 203 on which a substrate with an a-Si film 202 is placed, and the substrate with the a-Si film 202 can move by the movement of the substrate-transport stage 203 horizontally and in both the lengthwise and crosswise directions. In addition, up above the substrate with the a-Si film 201, a chamber window 204 through which a laser beam is entered is provided so that the substrate with the a-Si film 202 can be irradiated with a laser beam 206 oscillated by a pulse laser oscillator 205 via a light attenuator 207, a reflecting mirror 208, an optical system 209 for forming light, and a reflecting mirror 210. Moreover, in the chamber 201, a cooling system is mounted, and thus by cooling the inside of the chamber, the substrate can be cooled to a predetermined temperature lower than room temperature.

The above-described cooling system comprises, as means for cooling the substrate, a liquid nitrogen preservation tank 211, an inducting tube 212 for inducting nitrogen gas vaporized in the preservation tank into the chamber, and a discharging tube 213 for discharging the gas after the substrate has been subjected to the cooling process. The cooling system further comprises a thermocouple 214 serving as means for measuring the substrate temperature, a heater 215 serving as means for heating the substrate, and a controller 216 for controlling the means for cooling the substrate and the means for heating the substrate based on the temperature measured by the means for measuring the substrate temperature. As in this configuration, when the system has, in addition to the means for cooling the substrate, the means for measuring the substrate temperature, the means for heating the substrate, and the controller, the flexibility of setting the substrate cooling temperature improves, and accordingly it is possible to control the substrate temperature to desired temperatures.

Fabrication of a polysilicon film using the above-described apparatus is carried out as follows.

First, a glass substrate having formed thereon an a-Si film is prepared and the glass substrate is placed on a substrate-transport stage. The glass substrate with an a-Si film can be obtained, for example, by depositing an SiO₂ base film of about 300 nm in thickness on a glass substrate by the TEOS CVD method or the like so as to remove impurities from the glass, and then depositing an a-Si film of about 50 nm in thickness by the plasma CVD method. In order to remove hydrogen in the a-Si film fabricated by the plasma CVD method, usually as a dehydrogenation step, a heat treatment is performed at 450° C. for one hour.

Next, the inside of the process chamber is cooled using the cooling system to cool the glass substrate. The substrate temperature is preferably 10° C. or lower. This is because when the allowable range of energy density is approximately 40 mJ/cm², stable fabrication can be obtained

Subsequently, as allowing the glass substrate with the a-Si film to move horizontally and in both the lengthwise and crosswise directions, an excimer laser is irradiated to the a-Si film to fuse and crystallize, thereby forming a p-Si film. The laser irradiation is performed, for example, by using an XeCl pulse laser (wavelength 308 nm), under conditions that irradiation is performed 300 times at one point with the substrate being moved. Note that the state of the silicon film changes with the number of laser beam irradiation times but the tendency that the lower the temperature of the substrate, the larger the energy range of the laser beam in which a p-Si film having high properties can be formed does not change, and thus a multiple number of irradiation does not cause any problems.

Then, the p-Si film thus obtained is exposed, for example, to hydrogen plasma at 450° C. for 2 hours. Thereby, a number of dangling bonds formed during crystallization disappear. Thus, a p-Si film without defects such as property variations can be obtained.

The principle of stably fabricating a p-Si film having high properties is explained in detail below.

In the case where a p-Si film is formed by irradiating a laser beam to an a-Si film, generally, by irradiating a film at an energy density of about 160 mJ/cm² or more at room temperature, fusion and crystallization occur and thus a p-Si film is formed. As described above, when a p-Si film has a large crystal grain size of about 1 μm, the film has high carrier mobility. In order to obtain such a large grain size and to prevent defects such as deterioration and ablation from occurring, the film needs to be irradiated at room temperature and at an energy density in the range from 370 mJ/cm² to 380 mJ/cm². It is, however, difficult to control the laser beam within such a narrow range (10 mJ/cm²). On the other hand, in the present embodiment, in the case, for example, where the substrate is cooled to a temperature of −50° C., in order to form a p-Si with a large grain size of 1 μm or more without defects such as deterioration and ablation, the film should be irradiated with a laser beam at an energy density in the range from 395 mJ/cm² to 425 mJ/cm². Hence, by cooling the substrate, it is possible to control the laser beam in a wide range (30 mJ/cm²) and therefore a p-Si film with high properties can be stably fabricated. Note that the above-described values of energy density of laser beam may vary with evaluation methods even when the intensity of laser beam is the same, and thus the above numerical values are taken just as approximate.

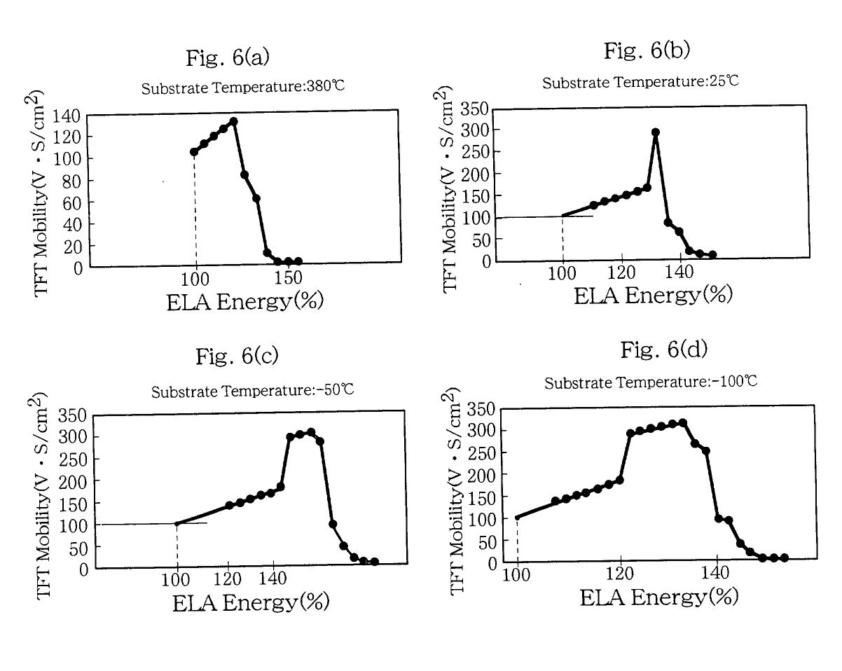

FIG. 6 shows the field-effect mobility (mobility) of n-ch for the case where polysilicon was formed by changing laser energy under conditions of a substrate temperature being 380° C., room temperature, −50° C., and −100° C., and subsequently a TFT was fabricated. The graph shows that while the mobility of the region having a large grain size is over 250 cm²/VS, the lower the substrate temperature, the wider the allowable range of laser energy.

Generally, one of the reasons for variations or shifts in Vt properties is due to the phenomenon that upon laser annealing not only the temperature of the film but also the temperatures of the base film and substrate are elevated and therefore impurities in the substrate diffuse into the base film and non-single crystal film. In recent years, in particular, in order to obtain a non-single crystal film with high properties, there has been a tendency to increase the laser intensity, and as a result the influence of the diffusion of impurities is becoming greater. However, as in the present embodiment, when laser annealing is performed with the substrate having been cooled, impurity diffusion is suppressed. Thus, a polycrystalline thin film with stable properties such as Vt properties can be obtained.

### EMBODIMENT 5

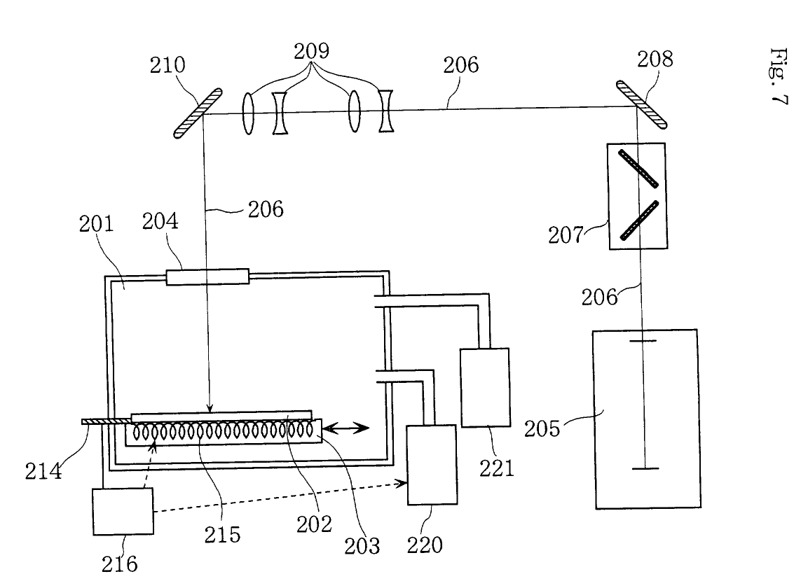

FIG. 7 is a structural view schematically showing an apparatus for fabricating a polysilicon film according to the present embodiment. This fabrication apparatus is different from the apparatus in Embodiment 4 in that the apparatus has a different cooling system.

A cooling system of this apparatus comprises an He freezer 220 serving as a cooler, a vacuum device 221 for degassing the chamber, a heater 215 serving as a heating device, a thermocouple 214 serving as a substrate temperature measuring system, and a controller 216. When the apparatus is provided with such a cooling system, the flexibility of setting the substrate cooling temperature increases, and accordingly it is possible to control the substrate temperature to desired temperatures. The He freezer 220 is a device for cooling a substrate by circulating the vaporization and liquefaction of liquid helium. With this device, it became possible to easily cool the substrate to cryogenic temperatures and the maintenance became easier.

The method of fabricating a p-Si film using the above-described apparatus is the same as that described in Embodiment 4 except for the method of cooling the substrate, and therefore the explanation thereof is omitted.

### EMBODIMENT 6

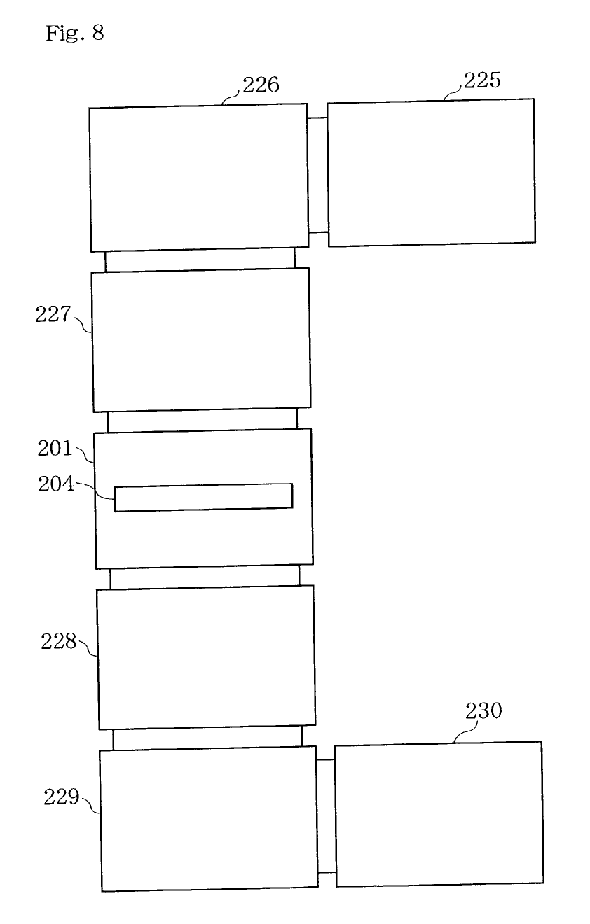

FIG. 8 is a structural view schematically showing an apparatus for fabricating a polysilicon film according to the present embodiment. This fabrication apparatus comprises, in addition to a process chamber 201, a conveyor for transporting the substrate in 225, a chamber for cooling a first substrate 226, a chamber for cooling a second substrate 227, a chamber for heating the first substrate 228, a chamber for heating the second substrate 229, and a conveyor for transporting the substrate out 230.

In the above-described apparatus, while a substrate is crystallized in the process chamber 9, other substrates to be subsequently processed are controlled to setting temperatures in the chambers 226 and 227 for cooling the substrate. In addition, substrates having been crystallized are allowed to regain room temperature in the chambers 228 and 229 for heating the substrate, while another substrate to be subsequently processed is being crystallized in the process chamber 201. With such an apparatus, almost no time is required to cool and heat the substrate, improving productivity.

The p-Si films fabricated using the fabrication methods and fabrication apparatuses described in the foregoing Embodiments 4 to 6 can be used as the semiconductor films for thin film transistors. In addition, such p-Si films can be applied to thin film transistor arrays and image display devices such as liquid crystal display devices.

### EMBODIMENT 7

This embodiment is a combination of the foregoing Embodiments 1 and 4. Specifically, after the substrate has been cooled, excimer laser irradiation is performed, followed by test beam irradiation, and then diffracted light is monitored. Based on the results of the monitoring, laser irradiation is performed again. The p-Si film thus fabricated is such a film that was laser annealed in a wide laser allowable range and also the film was obtained by, after examining defects in crystallinity using diffracted light, performing laser annealing again, and therefore a film with, in particular, uniform crystallinity is obtained.

### EMBODIMENT 8

The present embodiment relates to p-Si films fabricated in each of the foregoing embodiments, wherein physical quantities using the main peak wavelength of diffracted light generated when light is irradiated and the half-width of the wavelength are specified.

The p-Si films according to the present embodiment satisfy the following expression (1):

Δλ/λ≦0.3 (1)

where λ (nm) is the main peak wavelength of diffracted light obtained by test beam irradiation and Δλ (nm) is the half-width of the main peak wavelength.

When the above expression (1) is satisfied, the diffracted light of test beam is sharp, and therefore the micro-rough structure of the p-Si film surface has high regularity. Accordingly, the p-Si film does not have grain size variations and has a high periodicity.

Up to now, in order to increase the product yield of the TFT, various attempts have been made; however, as for the p-Si film, attempts were made mainly to suppress variations in crystal grain size. Under such circumstances, the present inventors thought that it is important not only to suppress variations in crystal grain size, but also to increase periodicity. In other words, the present inventors came up with an idea that when the film is formed in accordance with a certain order, uniform film properties are obtained, and therefore yield can be increased. Thus, the present inventors noted that in the above-described fabrication method using diffracted light, the generation of diffracted light was resulting from the regular micro-rough structure, and various investigations were carried out on the measured values of diffracted light. As a result, it was found that when the above expression (1) is satisfied, a high periodicity and good yield are achieved.

Next, the relationship between Δλ/λ and yield (which has a correlation with periodicity) is explained in detail below.

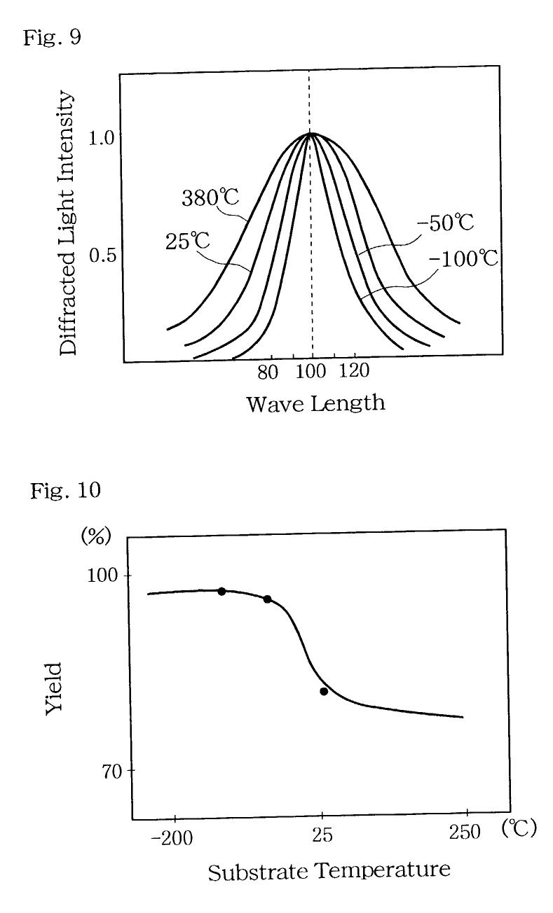

FIG. 9 shows the results of measurements of diffracted light intensities. The diffracted light intensities were obtained by irradiating white light, serving as the test beam, to a p-Si film fabricated by setting such conditions that a substrate temperature being 380° C., room temperature (25° C.), −50° C., and −100° C., and then laser annealing, and diffracted light was divided into wavelengths. In the figure, the horizontal axis indicates wavelength distributions when the main peak wavelength λ is 100%. From this figure, it can be seen that the higher the substrate temperature, the greater Δλ/λ is. For reference, specific numerical values are provided such as; Δλ/λ=0.45 at a substrate temperature of −380° C., 0.35 at room temperature, 0.26 at −50° C., and 0.2 at −100° C.

FIG. 10 shows the relationship between substrate temperature and yield. From this figure, it can be seen that yield increases dramatically when the film is fabricated with a substrate temperature being slightly lower than room temperature.

From FIGS. 9 and 10, it was confirmed that good yield (high periodicity) was achieved when Δλ/λ was 0.3 or lower.

The variation σ/λ(σ: standard deviation) of the main peak wavelength of diffracted light, which is generated when a test beam is irradiated to a plurality of regions on a p-Si film formed on the substrate, is preferably 0.15 or less, and more preferably 0.10.

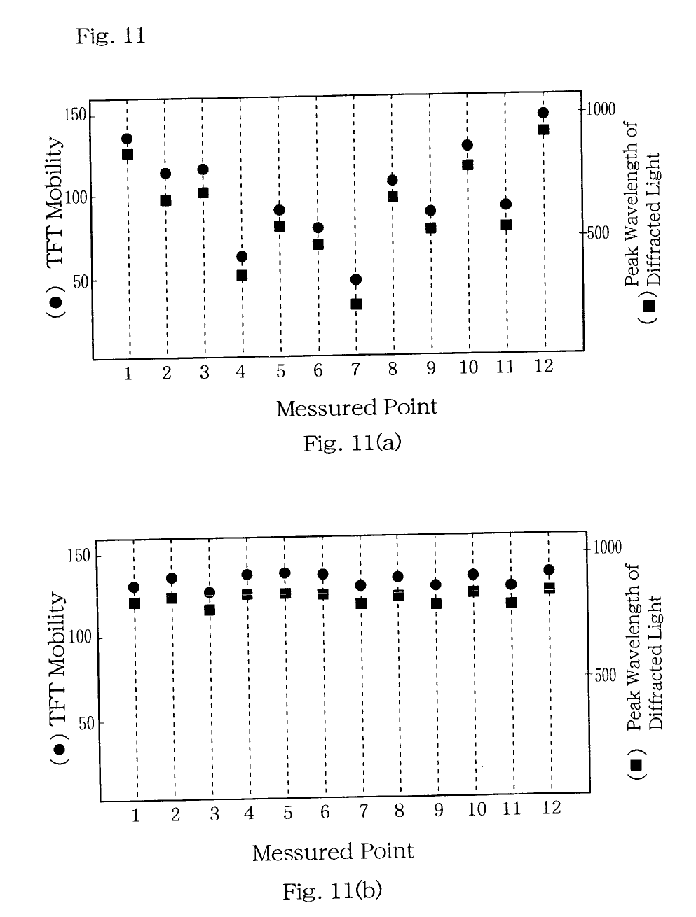

FIGS. 11(a) and 11(b) show the electron mobility and the main peak wavelength of diffracted light at each measuring point (12 points) of a p-Si film formed on the substrate. Note that FIG. 11(a) shows the case of a p-Si film fabricated by a prior art fabrication method and FIG. 11(b) shows the case of a p-Si film fabricated by a fabrication method described in Embodiment 1. From these drawings, it was confirmed that the p-Si film fabricated in Embodiment 1 had less variations than the prior art p-Si film.

### EMBODIMENT 8

The present embodiment relates to p-Si films fabricated in each of the foregoing embodiments, wherein physical quantities using the exit angle of diffracted light of a test beam and the half-width of the angle are specified.

The p-Si films according to the present embodiment satisfy the following expression (2):

sin(Φ+ΔΦ/2)/sin Φ≦0.15 (2)

where Φ (degree) is the exit angle of diffracted light having the highest light intensity among diffracted light obtained by irradiating monochromatic light serving as a test beam and ΔΦ (degree) is the half-width of the exit angle of the diffracted light.

When the above expression (2) is satisfied, the diffracted light of test beam is sharp, and therefore the micro-rough structure of the p-Si film surface has high regularity. Accordingly, the p-Si film does not have grain size variations and has a good periodicity.

Next, the relationship between sin(Φ+ΔΦ/2)/sin Φ and yield (which has a correlation with periodicity) is explained in detail below.

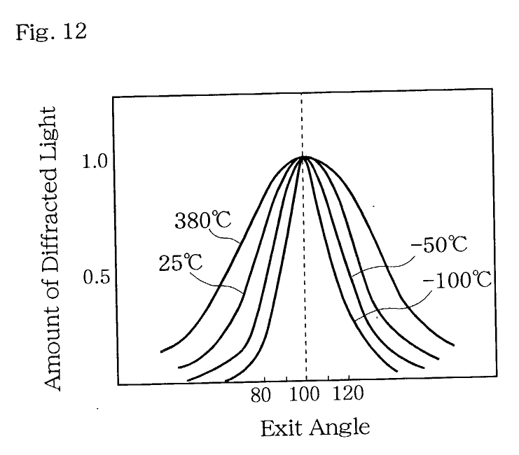

FIG. 12 shows the results of measurements of the angle of a diffracted light detector at which the maximum amount of light can be obtained and distributions in accordance with angles, when monochromatic light as a test beam is irradiated to a p-Si film fabricated by setting such conditions that a substrate temperature being 380° C., room temperature (25° C.), −50° C., and −100° C., and then laser annealing. In the figure, the horizontal axis indicates distributions when the exit angle Φ at the time of detecting the maximum amount of light is 100. From the figure, it can be seen that the lower the substrate temperature, the sharper the diffracted light. For reference, specific numerical values are provided such as; sin(Φ+ΔΦ/2)/sin Φ=0.22 at a substrate temperature of −380° C., 0.17 at room temperature, 0.13 at −50° C., and 0.1 at 100° C.

From FIGS. 12 and 10, it was confirmed that when sin(Φ+ΔΦ/2)/sin Φ is 0.15 or less, good yield (periodicity) was achieved.

The variation σ/(sin Φ) (σ: standard deviation) of the strongest diffracted light, which is generated when a test beam is irradiated to a plurality of regions on a p-Si film formed on the substrate, is preferably 0.15 or less, and more preferably 0.10.

### EMBODIMENT 9

The present embodiment relates to p-Si films fabricated in each of the foregoing embodiments, wherein the peak shift quantity by Raman spectrometry is specified.

In the p-Si films according to the present embodiment, the peak shift quantity by Raman spectrometry is 3 cm⁻¹ or less in comparison with a single crystal film.

In general, film distortion occurs during the period from hardening of polysilicon to cooling of the substrate, due to the difference in thermal expansion rate between the base film and the p-Si film. However, in a p-Si film fabricated by laser annealing with the substrate having been cooled, the peak shift quantity is within the above-described range, and therefore the film distortion is small. Accordingly, crack defects rarely occur and an advantageous effect such as high carrier mobility is provided.

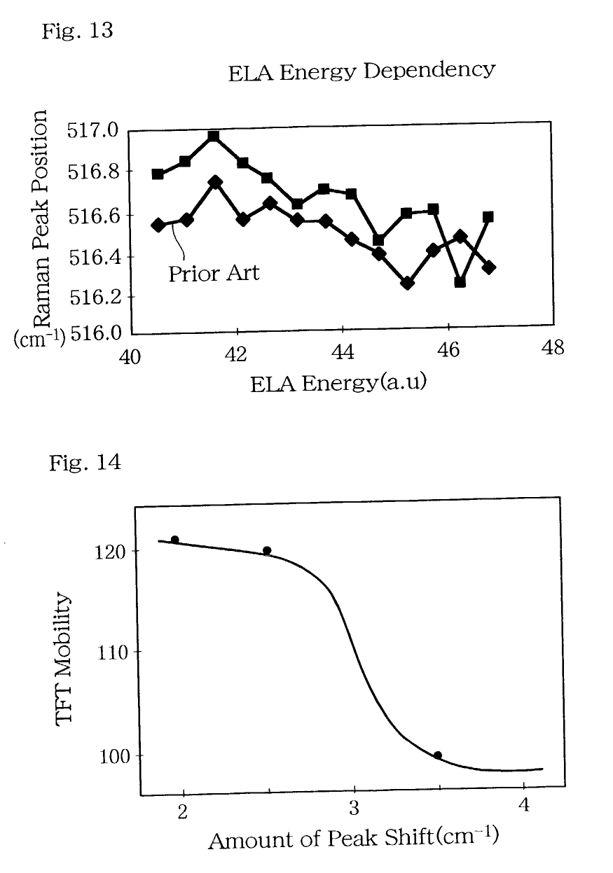

FIG. 13 shows the relationship between ELA energy and Raman peak position. From this figure, it was confirmed that p-Si films fabricated in Embodiments 1 and 4 have greater Raman peak positions and smaller shift quantities from the Raman peak position of a non-single crystal film (approximately 520 cm⁻¹), than a p-Si film fabricated by a conventional method.

FIG. 14 shows the relationship between peak shift quantity and carrier mobility. From this figure, it was confirmed that when the peak shift quantity is 3 cm⁻¹ or less, carrier mobility increases dramatically.

### EMBODIMENT 10

The present embodiment relates to p-Si films fabricated in each of the foregoing embodiments, wherein there are regions having differing main peak wavelengths of diffracted light or differing exit angles of the strongest diffracted light.

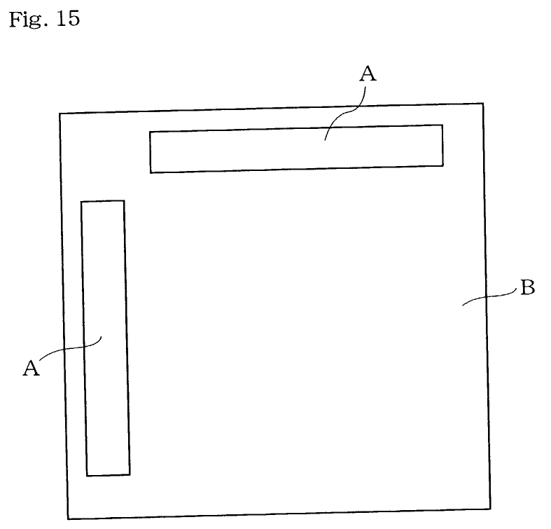

In a p-Si film according to the present embodiment, as shown in, for example, FIG. 15, the peak wavelengths of diffracted light generated by light irradiation or the exit angles of the strongest diffracted light generated by light irradiation are different between the regions A and B. Accordingly, even though a film is made of the same polysilicon, the film has regions having differing carrier mobilities or the like. It is preferable that the difference in peak wavelength be 200 nm or more, because with these values, differing regions can be clearly divided.

A p-Si film with the above-described configuration can be easily fabricated by using the above-described fabrication apparatuses and methods. Specifically, with the above-described fabrication apparatuses and methods, crystallization can be performed by using, as the index, the main peak wavelength of diffracted light or the exit angle of the strongest diffracted light, and thus by adjusting these values to predetermined values and then performing laser annealing, regions having differing properties can be formed.

A p-Si film having regions divided in such a manner that is shown in FIG. 15 can be used in manufacturing driving circuit-contained liquid crystal display devices.

In general, in a driving circuit-contained liquid crystal display device, TFTs in a pixel portion and TFTs in a driving circuit portion require differing properties. In other words, the TFTs in the pixel portion require, in particular, uniformity between the TFTs in the pixel portion so as not to cause variations in image display, while the TFTs in the driving circuit portion highly require fast response time rather than uniformity. However, in the past, uniform laser beam irradiation was carried out in fabricating TFTs in the pixel and driving circuit portions, and therefore satisfactory properties were not imparted to the TFTs in either portion. On the other hand, in the present invention, because a p-Si film exhibiting desired crystallinity can be formed using diffracted light as the index, by forming the pixel portion and the driving circuit portion separately, it is possible to form a film that satisfies required properties for each portion.

### EMBODIMENT 11

This embodiment relates to a p-Si film formed on the substrate with a base film interposed therebetween, wherein impurity incorporation from the substrate is minimized.

In a substrate with a p-Si film according to this embodiment, the impurity concentration of a base film disposed 1000 Å away from the interface between the substrate and the base film is 0.001% or less than that of the substrate.

Such a substrate with a p-Si film can be obtained by using the fabrication apparatus and method in accordance with Embodiment 4, wherein laser annealing is performed with the substrate having been cooled.

Conventionally, in order to improve the properties of a p-Si film, the substrate is heated and then laser annealed. However, there has been a problem that when the substrate temperature was elevated, impurities seeped out of the substrate and got into the p-Si film, deteriorating the properties of the p-Si film. In order to overcome such a problem, a base film was provided to suppress impurity incorporation into the p-Si film, but still a great amount of impurities were incorporated into the p-Si film. On the other hand, according to the method of the present invention, a heat quantity given to a-Si is the same as that of conventional methods and seeping of impurities from the substrate can be suppressed. Thus, the base film can be made thin. In addition, distortion of the p-Si film can be suppressed to a low level and generation of crack defects can be suppressed, and therefore the process margin widens.

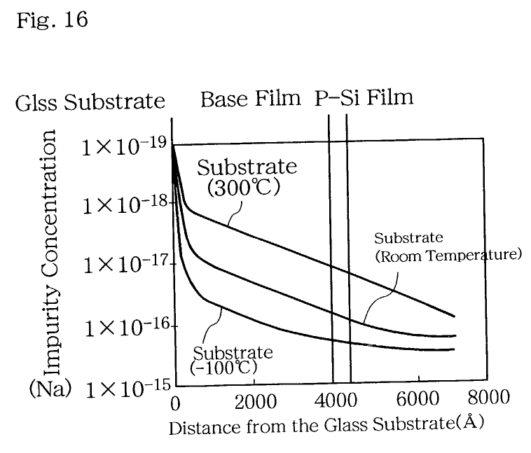

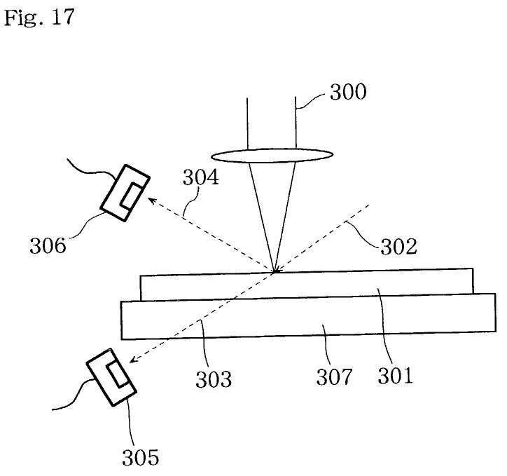

FIG. 16 shows the relationship between the distance from the substrate surface and impurity concentration. From this drawing, it was confirmed that when the substrate is cooled and laser annealed, seeping of Na contained in the glass substrate can be suppressed. For reference, specific numerical values are provided as follows. As the substrate, a glass substrate with an Na concentration of 5×10²¹ cm⁻³ was used. When the substrate was heated to 300° C., the impurity concentration of the base film (located 1000 Å away from the substrate surface) was 3×10¹⁸ cm⁻³, when the substrate temperature was room temperature, 9×10¹⁶ cm⁻³, and when the substrate temperature was −100° C., 1.5×10¹⁶ cm⁻³.

### Embodiment 12

This embodiment relates to a p-Si film having a region that allows for measurement of diffracted light when monitoring by diffracted light.

In a p-Si film according to the present embodiment, a testing pattern is formed on a surface of the film where diffracted light can be measured, thereby enabling a process check. The testing pattern should be such a shape that includes a rectangle with a long side of 0.5 μm or more and a short side larger than a wavelength to be measured, with the p-Si film being exposed. In measurement of diffracted light, the length is important so as to improve measurement accuracy and thus the shape is not necessarily a square.

For measurement of diffracted light, the p-Si film is not necessarily exposed and may be covered with a transparent thin film or a metal thin film as long as the film does not disturb the micro-rough structure. When the p-Si film is covered with a metal thin film with a high light reflectivity, diffracted light can be measured more accurately. It is preferable that the thickness of such a thin film be 500 Å or less.

The present invention has been described above with reference to several embodiments thereof. However, the present invention is, of course, not limited to these embodiments. For example, the present invention can be applied to chalcogenide films used in CD-RW, MgO films used in PDP, and the like.

### INDUSTRIAL APPLICABILITY

As described above, in the present invention, a non-single crystal film is tested by monitoring diffracted light and crystallized by giving feedback, based on the test results, to the irradiation conditions such as laser intensity, and therefore variations in grain size are reduced and the periodicity of grain size is improved. As a result, a non-single crystal film with stable properties such as mobility can be obtained.

In addition, in the present invention, the substrate is cooled and laser annealed with a wider allowable range of laser energy, and thus variations in grain size are reduced and the periodicity of grain size is improved. As a result, a non-single crystal film with stable properties such as mobility can be obtained.

Consequently, the present invention is effectively applied to fields in which higher properties are demanded, such as thin film transistors, thin film transistor arrays using such thin film transistors, and image display devices using such thin film transistor arrays such as liquid crystal display devices.

What is claimed is:

1. A method of fabricating a non-single crystal film fabricated by irradiating a laser beam to an amorphous film or microcrystalline film, wherein crystallization or recrystallization is carried out by irradiating a test beam to a region where the laser beam has been irradiated and optimizing an irradiation condition of the laser beam so that a measured value of diffracted light generated from the non-single crystal film becomes a predetermined value.

2. The method of fabricating a non-single crystal film according to claim 1, wherein the measured value of the diffracted light is a light intensity of the diffracted light.

3. The method of fabricating a non-single crystal film according to claim 1, wherein the irradiation condition of the laser beam is at least one selected from the group consisting of energy, the number of irradiation times, frequency, irradiation interval, scanning speed, and beam intensity distribution.

4. A method of fabricating a non-single crystal film fabricated by irradiating a laser beam to an amorphous film or microcrystalline film as scanning, wherein crystallization or recrystallization is carried out by irradiating a test beam to a region where the laser beam has been irradiated, recording measured values of diffracted light generated from the non-single crystal film, and irradiating a laser beam again to a region whose measured value does not match a predetermined value.

5. An apparatus for fabricating a non-single crystal film comprising: a laser beam; an optical system for forming a laser beam into a predetermined shape; a light source for a test beam; and a diffracted light detector,
wherein crystallization or recrystallization is carried out by irradiating a test beam from the light source to a non-single crystal film fabricated using the laser beam formed by the optical system, detecting, by the diffracted light detector, diffracted light generated from the non-single crystal film, and optimizing an irradiation condition of the laser beam so that a measured value obtained by the detection becomes a predetermined value.

6. The apparatus for fabricating a non-single crystal film according to claim 5, wherein the measured value of the diffracted light is a light intensity of the diffracted light.

7. The apparatus for fabricating a non-single crystal film according to claim 5, wherein the irradiation condition of the laser beam is at least one selected from the group consisting of energy, the number of irradiation times, frequency, irradiation interval, scanning speed, and beam intensity distribution.

8. A method of testing a non-single crystal film, wherein a non-single crystal film is irradiated with a test beam and diffracted light generated from the non-single crystal film is detected.

9. The method of testing a non-single crystal film according to claim 8, wherein the diffracted light is divided into wavelengths.

10. The method of testing a non-single crystal film according to claim 8, wherein an angle distribution or position distribution of the diffracted light is measured.

11. An apparatus for testing a non-single crystal film comprising: a light source for a test beam; and a diffracted light detector,
wherein a non-single crystal film is irradiated with a test beam from the light source and an intensity of diffracted light generated from the non-single crystal film is detected.

12. The apparatus for testing a non-single crystal film according to claim 11, wherein means for dividing the diffracted light into wavelengths is provided.

13. The apparatus for testing a non-single crystal film according to claim 11, wherein the diffracted light detector is a device for measuring an angle distribution or position distribution of the light intensity of the diffracted light.

14. A method of fabricating a non-single crystal film comprising at least: depositing an amorphous film or microcrystalline film on a substrate; and crystallizing, by fusion, the amorphous film or the microcrystalline film by irradiating a laser to the amorphous film or the microcrystalline film, thereby forming a non-single crystal film,
wherein the crystallizating is carried out with the substrate having been cooled.

15. The method of fabricating a non-single crystal film according to claim 14, wherein in the crystallizing, a temperature of the substrate is maintained at 10° C. or lower.

16. An apparatus for fabricating a non-single crystal film fabricated by irradiating a laser beam to an amorphous film or microcrystalline film formed on a substrate, wherein means for cooling the substrate is provided.

17. The apparatus for fabricating a non-single crystal film according to claim 16, wherein means for measuring a temperature of the substrate, means for heating the substrate, and means for controlling the means for cooling the substrate and the means for heating the substrate, based on a measured value obtained by the means for measuring the temperature of the substrate, are provided.

18. A non-single crystal film formed on a substrate, wherein the film satisfies the following expression (1):
Δλ/λ≦0.3 (1)
where λ (nm) is a wavelength of a main peak of diffracted light obtained by light irradiation and Δλ (nm) is a half-width of the wavelength of the main peak.

19. A non-single crystal film formed on a substrate, wherein the film satisfies the following expression (2):
sin(Φ+ΔΦ/2)/sin Φ≦0.15 (2)
where Φ (degree) is an exit angle of strongest diffracted light obtained by monochromatic light irradiation and ΔΦ is a half-width of the angle of the diffracted light.

20. The non-single crystal film according to claim 18, wherein the film satisfies the following expression (3):
σ/λ≦0.15 (3)
where σ represents a standard deviation.

21. The non-single crystal film according to claim 19, the film satisfies the following expression (4):
σ/(sin Φ)≦0.15 (0.15)
where σ represents a standard deviation.

22. A non-single crystal film formed on a substrate, wherein a surface of the thin film has regions having differing peak wavelengths of diffracted light generated by light irradiation.

23. A non-single crystal semiconductor film for a driving circuit-contained liquid crystal display device, wherein a region corresponding to a pixel portion and a region corresponding to a driving circuit portion have differing peak wavelengths of diffracted light.

24. The non-single crystal film according to claim 22, wherein the peak wavelengths between the regions differ by 200 nm or more.

25. A non-single crystal film formed on a substrate, wherein a surface of the thin film has regions having differing exit angles of diffracted light.

26. A non-single crystal semiconductor film for a driving circuit-contained liquid crystal display device, wherein a region corresponding to a pixel portion and a region corresponding to a driving circuit portion have differing exit angles of diffracted light.

27. A non-single crystal film formed on a substrate, wherein a peak shift quantity by Raman spectrometry is 3 cm⁻¹ or less than that of single crystal.

28. A substrate with a non-single crystal film fabricated by irradiating a laser beam to an amorphous film or microcrystalline film formed on a substrate surface with a base film interposed therebetween, wherein an impurity concentration of the base film is 0.001% or less than that of the substrate.

29. A non-single crystal film formed on a substrate, wherein a surface of the thin film has a region in which diffracted light is generated by light irradiation and the diffracted light can be detected.

30. The non-single crystal film according to claim 29, wherein the region includes a rectangle such that at least one side thereof is 0.5 mm or more.

31. A thin film transistor, wherein a non-single crystal film in accordance with any one of claims 18 to 30 is used as a semiconductor film.

32. A thin film transistor array, wherein a thin film transistor in accordance with claim 31 is formed on a substrate.

33. An image display device, wherein a thin film transistor array in accordance with claim 32 is used.
